(19) United States
(12) Patent Application Publication
(10) Pub. No.: US 2003/0085435 A1
(43) Pub. Date: May 8, 2003

(54) Transistor structure and process to fabricate same

(76) Inventor: Zhongze Wang, Boise, ID (US)

Correspondence Address: David J. Paul, Agent for Applicant, Micron Technology, Inc., 8000 S. Federal Way, MS 525, Boise, ID, 83716, US

(21) Appl. No.: 10/008,854

(22) Filed: Nov. 2, 2001

(51) Int. Cl. H01L 21/336; H01L 21/8234; H01L 29/76; H01L 31/119

(52) U.S. Cl. 257/396; 257/288; 438/197; 257/330; 438/259; 438/271; 257/368; 438/225

(57) ABSTRACT

A transistor structure and method to fabricate same, the semiconductor transistor structure comprising a transistor having an effective channel width that is greater than a lateral surface dimension spanned by an overlying transistor gate. A method of forming a transistor structure during semiconductor fabrication comprising the steps of forming at least one recessed region into a semiconductive material defined as an active area for the transistor; forming a transistor gate dielectric material directly and substantially comformally on the semiconductive material and into the at least one recessed region; and forming a transistor gate electrode substantially comformally overlying the transistor gate dielectric material and extending into the at least one recessed region such that the transistor gate electrode spans a width of the active area.

### FIELD OF THE INVENTION

This invention relates to a semiconductor device and fabrication thereof and, more particularly, to a semiconductor transistor structure and fabrication thereof.

### BACKGROUND OF THE INVENTION

Increasing transistor current drive for the transistors used in integrated circuits is a desirable goal. The drive current of a field effect transistor is proportional to its channel width (W) and inversely proportional to its channel length (L). Thus, increasing W increases current drive of the transistor. It is conventional practice to increase W by increasing the overall size of the transistor. However, this approach requires a greater area of the integrated circuit, which is an undesirable tradeoff for semiconductor devices that require a high density of active devices (i.e., transistors). This is particularly true for memory devices such as dynamic random access memory (DRAM) and static random access memory (SRAM) devices.

In a conventional fabrication process, the transistor is formed on top of a planar silicon surface. Drain to Source current (I_{ds}) is proportional to W, which is the physical width of the transistor channel as well as the top down depth of the transistor channel.

A significant focus of the present invention is the development of a transistor having effective increased width and depth of a transistor channel within a confined area. Thus, the present invention comprises a transistor structure with increased effective channel width and a method to fabricate same that will become apparent to those skilled in the art from the following disclosure.

### SUMMARY OF THE INVENTION

Exemplary embodiments of the present invention include a transistor structure and a method to fabricate same. A semiconductor transistor structure comprises a transistor having an effective channel width that is greater than a lateral surface, which is spanned by an overlying transistor gate.

A method of forming the inventive transistor structure during semiconductor fabrication comprises forming at least one recessed region into a semiconductive material defined as an active area for the transistor, forming a transistor gate dielectric material directly and substantially conformally on the semiconductive material, and forming a transistor gate electrode substantially conformally overlying the transistor gate dielectric material such that the transistor gate electrode spans a width of the active area.

### BRIEF DESCRIPTION OF THE DRAWINGS

FIG. 1 is a top-down view of an exemplary transistor formed on a semiconductor substrate.

FIG. 2 is a cross-sectional view taken through line 1-1′ of FIG. 1 depicting related art showing the gate, gate oxide and active area (with field oxide isolating the active area) of a typical field effect transistor that is conventional in semiconductor fabrication.

FIG. 3 is a cross-sectional view taken through line 1-1′ of FIG. 1 after formation of a field oxide followed by patterning of the underlying silicon substrate according to the present invention.

FIG. 4 is a subsequent cross-sectional view taken from FIG. 3 following the etching of the silicon substrate followed by a photoresist strip.

FIG. 5 is a subsequent cross-sectional view taken from FIG. 4 following the formation of a transistor gate oxide and the formation of a polysilicon layer.

### DETAILED DESCRIPTION OF THE INVENTION

Exemplary implementations of the present invention are directed to a unique transistor structure for use in semiconductor devices and a process to fabricated same, as depicted in FIGS. 3-5.

The following exemplary implementations are in reference to a transistor structure and the fabrication thereof in a semiconductor assembly. While the concepts of the present invention are conducive to the fabrication of a field effect transistor, the concepts taught herein may be applied to other semiconductor devices that would likewise benefit from the use of the transistor structure and process disclosed herein. Therefore, the depiction of the present invention in reference to a field effect transistor and the manufacture thereof, are not meant to so limit the extent to which one skilled in the art might apply the concepts taught hereinafter.

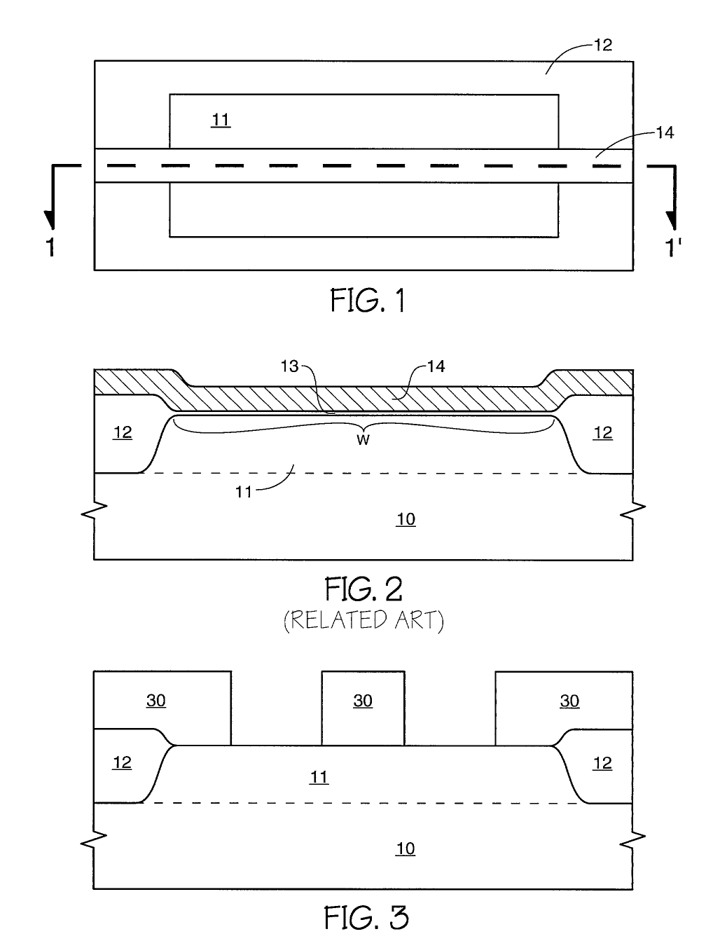

Referring to FIG. 1, a top-down view of transistor formed for a semiconductor device is depicted. As seen in FIG. 1, a portion of a semiconductor assembly, such as a silicon wafer, shows an active area 11 formed into a silicon substrate. Active area 11 is isolated by a surrounding field oxide region 12, a polysilicon gate 14 spans active area 11 and is separated therefrom by a gate oxide layer (not shown).

FIG. 2 is a cross-sectional view of FIG. 1 taken through lines 1-1′ and depicts an exemplary transistor structure used throughout the semiconductor industry. Referring now to FIG. 2, a semiconductive substrate 10, such as a silicon wafer, has been patterned to define an active area 10 for a typical field effect transistor. Field oxide 12 has been formed to isolate active area 11. A patterned transistor gate 14, formed from polysilicon, spans the width of active area 11 and is separated therefrom by gate oxide 13. The channel width of this conventional transistor is defined by dimension (W) that extends in a linearly fashion across active area 11.

An exemplary implementation of the present invention is depicted in FIGS. 3-5. Referring now to FIG. 3, a semiconductive substrate 10, such as a silicon wafer, is patterned to define an active area 11 for an exemplary implementation for a field effect transistor structure of the present invention. Field oxide 12 is then formed to isolate active area 11. Next, photoresist material 30 is patterned in preparation for a subsequent etch, which will be used to form trenches into active area 11.

Referring now to FIG. 4, trenches 40 and 41 are etched transversely into silicon active area 11 between boundaries of field oxide 12 and then photoresist material 30 (seen in FIG. 3) is stripped. Trenches 40 and 41 add to the effective transistor channel width, now defined by dimensions (a), (b), (c), (d), (e), (f), (g), (h) and (i), of a subsequently formed transistor, such as a field effect transistor. The effective channel width (W_{eff}) of the transistor is now defined by the equation: W_{eff}=a+b+c+d+e+f+g+h+i. Though the exemplary implementation of the present invention shows the formation of two trenches into active area 11, more or less trenches may be formed, depending on area constraints and manufacturing equipment limitations. Also, varying the depth of the trench formed may be used to determine and vary the overall W_{eff} of the transistor channel width.

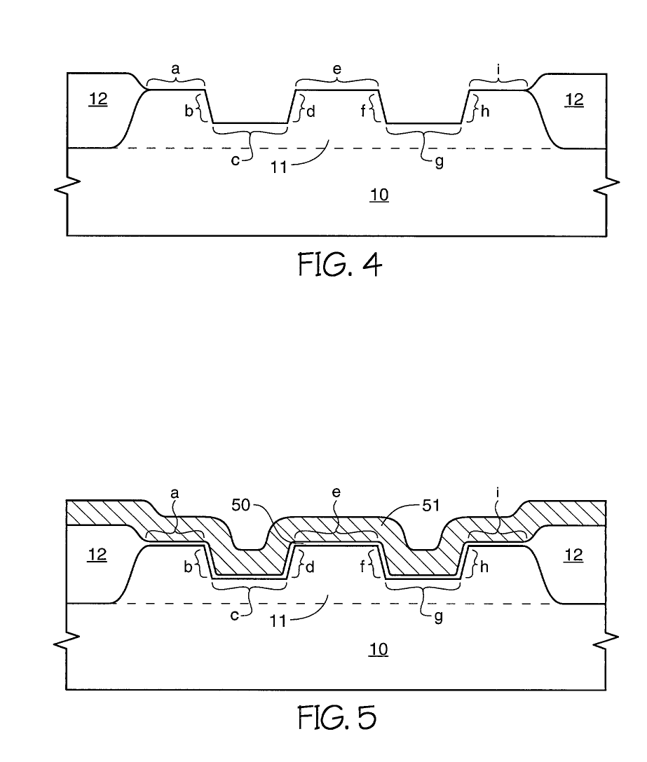

The physical channel width of a transistor is an important factor in determining current drive. For example, a field effect transistor drive current I_{ds} is directly proportional to its channel width. Therefore, by increasing the transistor channel width, the drive current of the transistor is increased. The present invention accomplishes increasing the transistor channel width by increasing the effective channel width dimension and does so by maintaining the transistor size, which is confined to a predetermined area. This significant accomplishment is easily appreciated by comparing the transistor channel width of FIG. 2, depicting a conventional transistor, to the transistor channel width of FIGS. 4 and 5, depicting an implementation of an exemplary transistor of the present invention.

When comparing FIG. 2 to FIG. 5 (both of which are intentionally drawn to the same scale), both transistors occupy the same surface area and yet the channel width of the conventional transistor of FIG. 2 is defined by the linearly-extending dimension (W), while the channel width of the transistor of the present invention, shown in FIG. 5, is defined by: W_{eff}=a+b+c+d+e+f+g+h+i, which is greater that the dimension (W) of the conventional transistor due to the convoluted topography of active area 11. The current drive for the transistor of the present invention is thereby increased significantly over the industry standard transistor depending on how much larger W_{eff} is than W.

Referring now to FIG. 5, a substantially comformal oxide 50 is formed over silicon active area 11, followed by the formation of a substantially conformal layer of polysilicon 51. Oxide 50 and polysilicon 51 are subsequently patterned and etched together to form transistor gate 14 and underlying transistor gate oxide 13, depicted in FIG. 1.

The transistor is then completed by conventional fabrication methods known to those skilled in the art, such as conductive dopant implanting to form the source and drain electrodes combined with the formation of gate insulation, such as gate spacers and an overlying gate oxide or nitride layer. The completed transistor may be of various types (i.e., field effect transistor, bipolar transistor, etc.) and may be used in numerous semiconductor applications and particularly in, but not limited to, DRAMs and SRAMs.

It is to be understood that, although the present invention has been described with reference to a preferred embodiment, various modifications, known to those skilled in the art, may be made to the disclosed structure and process herein without departing from the invention as recited in the several claims appended hereto.

What is claimed is:

1. A method of forming a transistor structure during semiconductor fabrication comprising the steps of:
forming at least one recessed region into a semiconductive material defined as an active area for said transistor structure;
forming a transistor gate dielectric material directly and substantially conformally on said semiconductive material and into said at least one recessed region; and
forming a transistor gate electrode substantially conformally overlying said transistor gate dielectric material such that said transistor gate electrode spans a width of said active area.

2. The method of claim 1, wherein said step of forming at least one recessed region comprises patterning and etching a trench into said active area to form said recessed region.

3. A method of forming a transistor structure during semiconductor fabrication comprising the steps of:
forming multiple recessed regions into a semiconductive material defined as an active area for said transistor structure;
forming a transistor gate dielectric material directly and substantially conformally on said semiconductive material and into said multiple recessed regions; and
forming a transistor gate electrode substantially conformally overlying said transistor gate dielectric material and into said multiple recessed regions such that said transistor gate electrode spans a width of said active area.

4. The method of claim 3, wherein said step of forming multiple recessed regions comprises patterning and etching a trench into said active area to form each said recessed region.

5. A method of forming a field effect transistor structure during semiconductor fabrication comprising the steps of:
forming a region having a convoluted topography into a semiconductive material, said region defined as an active area for said field effect transistor structure;
forming a field effect transistor gate dielectric material directly and substantially conformally on said region having said convoluted topography; and
forming a transistor gate electrode substantially conformally overlying said transistor gate dielectric material such that said transistor gate electrode spans a width of said active area.

6. The method of claim 5, wherein said step of forming a region having a convoluted topography comprises patterning and etching at least one trench into said active area.

7. The method of claim 5, wherein said step of forming a region having a convoluted topography comprises patterning and etching multiple trenches into said active area.

8. A semiconductor transistor structure comprising:
a transistor channel having at least one recessed region along a width thereof, said transistor channel having an effective channel width that is greater in dimension than an effective channel width a substantially planar transistor channel of a transistor having approximately the channel width of said semiconductor transistor structure.

9. The semiconductor transistor structure of claim 8 further comprising a transistor channel having at least one recessed region along its width.

10. The semiconductor transistor structure of claim 9 further comprising a transistor channel having multiple recessed regions along its width.

11. A semiconductor transistor structure comprising:
a transistor having an effective channel width that is greater than a lateral surface dimension spanned by an overlying transistor gate.

12. The semiconductor transistor structure of claim 11 further comprising a transistor channel having at least one recessed region along its width.

13. The semiconductor transistor structure of claim 11 further comprising a transistor channel having multiple recessed regions along its width.

14. A semiconductor field effect transistor device comprising:
a transistor channel having at least one recessed region along a width thereof, said transistor channel having an effective channel width that is greater in dimension than an effective channel width of a substantially planar transistor channel of a transistor having approximately the same channel width of said semiconductor transistor structure.

15. The semiconductor field effect transistor structure of claim 14 further comprising a transistor channel having at least one recessed region along its width.

16. The semiconductor field effect transistor structure of claim 14 further comprising a transistor channel having multiple recessed regions along its width.

17. A semiconductor field effect transistor structure comprising:
a transistor having an effective channel width that is greater than a linearly-extending dimension of a surface spanned by an overlying transistor gate.

18. The semiconductor field effect transistor structure of claim 17 further comprising a transistor channel having at least one recessed region along its width.

19. The semiconductor field effect transistor structure of claim 17 further comprising a transistor channel having multiple recessed regions along its width.
